(19) United States
(12) Patent Application Publication
(10) Pub. No.: US 2025/0331245 A1
(43) Pub. Date: Oct. 23, 2025

(54) SEMICONDUCTOR DEVICE WITH FIRST AND SECOND DOPANT DIFFUSION REGIONS

(71) Applicant: Huawei Digital Power Technologies Co., Ltd., Shenzhen (CN)

(72) Inventors: Samir Mouhoubi, Nuremberg (DE); Tomasz Sledziewski, Munich (DE)

(73) Assignee: Huawei Digital Power Technologies Co., Ltd., Shenzhen (CN)

(21) Appl. No.: 19/259,910

(22) Filed: Jul. 3, 2025

Related U.S. Application Data
(63) Continuation of application No. PCT/EP2023/071416, filed on Aug. 2, 2023.

(51) Int. Cl. H10D 62/10; H10D 62/00; H10D 62/832

(52) U.S. Cl. CPC H10D 62/109; H10D 62/054; H10D 62/058; H10D 62/8325

(57) ABSTRACT

A semiconductor device is provided, which comprises: a die layer; a trench extending into the die layer, wherein the trench comprises a trench bottom and trench side walls; a first dopant implantation region arranged below the trench bottom; a second dopant implantation region arranged below the first dopant implantation region; a first dopant diffusion layer extending laterally of the first dopant implantation region; and a second dopant diffusion layer extending laterally of the second dopant implantation region; wherein an extension of the second dopant diffusion region in the lateral direction matches an extension of the first dopant diffusion layer in the lateral direction.

### CROSS-REFERENCE TO RELATED APPLICATIONS

This application is a continuation of International Application No. PCT/EP2023/071416, filed on Aug. 2, 2023, the disclosure of which is hereby incorporated by reference in its entirety.

### TECHNICAL FIELD

Embodiments of this application relate to the field of Semiconductor Technology for power device applications, e.g. wide bandgap power devices. Embodiments of the disclosure relate to a semiconductor device with first and second doping diffusion regions and a method for manufacturing such semiconductor device by using a spacer.

### BACKGROUND

Vertical Power Semiconductor Devices, for example currently available SiC devices, show a given design window for optimized Rdson (Drain-Source on-resistance) performance. In order to further reduce Rdson, a pitch shrink is often planned in the next generations. This leads to a strong counter-productive Rdson increase because of enhanced Junction Field-Effect Transistor (JFET) action due to the presence of the body/wells in the MOS structure. Until today, no solution is available for such JFET effect handling when the pitch is reduced.

### SUMMARY

This disclosure provides a solution for overcoming the above limitations due to enhanced JFET action.

A solution for decreasing the pitch of a vertical power semiconductor device without a significant increase of the JFET effect is provided.

The foregoing and other objectives are achieved by the features of the independent claims. Further implementation forms are apparent from the dependent claims, the description and the figures.

Embodiments of the disclosure present a solution for controlling the JFET effect by controlling the body-to-body distance via a process with reduced misalignments sensitivity. A Silicon Carbide (SiC) multiple self-aligned body through spacers is disclosed.

The presence of a body/well in vertical power devices is unavoidable due to its essential functions like 1) Providing a body for formation of a channel region; 2) Shielding the dielectrics of the device (like the gate dielectric); and 3) Acting as preferential location for impact ionization; etc.

The distance between body to body is one key parameter to control the JFET effect: the longer this distance, the weaker is the JFET and thus, the better it is for current conduction. In that sense, one can understand that the longest distance possible is beneficial, however, advanced and new generations of technologies require a shrink of the device size/pitch (elementary cell) in order to reduce the device area and thus reduce the cost per die and the resistance per die. This pitch reduction results directly in a shorter body to body distance.

These competing effects result in an optimum design window (pitch range) in which the lowest Rdson values can be achieved (highest current capability). This is depicted in FIG. 1.

The body/well is usually implanted through regions defined by lithography. The control of the body-to-body distance is key and becomes more and more difficult in advanced technologies where the pitch (and thus all distances) are reduced.

As described above, the continuous pitch decrease needed for the future technologies results in: Stronger JFET effect with higher Rdson values which is counterproductive; and difficulties to control the device performance due to magnified lithography misalignments effects. Embodiments of the disclosure present a solution for controlling this JFET effect.

Formation of the body by a self-aligned implantation through a spacer is described in the following which is a less sensitive process to misalignments compared to lithography. Splitting the implantation of the self-aligned body in more than one step provides implantation of the deeper portion of the body through a thicker (wider) spacer than the shallower part.

The solution described herein is applicable to any power conversion system or architecture using semiconductor power devices. The solution is applicable when high blocking voltage, high current density and high switching frequency are required. The solution is applicable, as an example, in inductively switching circuits, where there is a need of current freewheeling, i.e., reverse conduction mode, during turn-off of a power semiconductor device. The solution is applicable to all power electronic systems targeting energy loss, application size and total application cost reduction.

Products applying the solution are all power electronics products, particularly DC and AC converters used in photovoltaics, electric vehicles, chargers and on-board chargers, data centers, railway, telecom, servers and others.

In order to describe the disclosure in detail, the following terms and notations will be used.
MOS Metal Oxide Semiconductor
FET Field Effect Transistor
MOSFET Metal Oxide Semiconductor Field Effect Transistor
IGBT Insulated Gate Bipolar Junction Transistor
SiC Silicon Carbide
CSL Current Spreading Layer
JFET Junction Field Effect Transistor
SBD Schottky Barrier Diode
JSBD Junction Schottky Barrier Diode
SSF Shockley Stacking Faults
BPD Basal Plane Dislocations

Device active area—area which conducts a forward electric current; it is smaller than a device total area.

Device total area—can be understood as a chip (die) area; consists of the active area and all peripheries, e.g. an edge termination, scribe lines (dicing streets), contact pads (e.g. a gate contact) and others.

Forward electric current—a main electric current flowing through a device during its on-state.

Edge termination—a region extending outside of the active area whose function is to reduce an electric field in outer part of a device.

Source—a region in MOSFET which injects majority carriers during the on-state.

Drain—a region in MOSFET which collects majority carriers during the on-state.

Emitter—a region in IGBT which injects majority carriers during the on-state.

Collector—a region in IGBT which collects majority carriers and injects minority carriers during the on-state.

Majority carriers—electric carriers (electrons or holes) which dominate in the forward electric current conduction; their density is much bigger higher than the density of minority carriers.

Minority carriers—electric carriers (electrons or holes) whose density is much lower than the density of the majority carriers.

Gate—a voltage-controlled region in MOSFET or IGBT which switches a device between the on-state and the off-state.

Drift layer—a region in MOSFET or IGBT which conducts the electric current in the on-state and sustains the largest portion of an applied voltage (blocking voltage) in the off-state (blocking state).

Channel—a region in a body region of MOSFET or in a base region of IGBT to which the electric carriers are injected from the source or from the emitter, respectively, and whose conduction is controlled by the gate.

Body region—a region in MOSFET of an opposite doping type to the doping type of the source and drift layer, which contains the channel and which creates a pn-junction with the drift layer.

Base region—a region in IGBT of an opposite doping type to the doping type of the source and drift layer, which contains the channel and which creates a pn-junction with the drift layer.

JFET region—a region between the body regions or base regions of MOSFET or IGBT, respectively.

CSL—a region below the JFET region whose function is to spread the electric current in order to reduce an on-state resistance.

According to a first aspect, the disclosure relates to a semiconductor device, comprising: a die layer; a trench extending into the die layer, the trench comprising a trench bottom and trench side walls; a first dopant implantation region arranged below the trench bottom; a second dopant implantation region arranged below the first dopant implantation region; a first dopant diffusion layer extending laterally of the first dopant implantation region; and a second dopant diffusion layer extending laterally of the second dopant implantation region; wherein an extension of the second dopant diffusion region in the lateral direction matches an extension of the first dopant diffusion layer in the lateral direction.

Such device provides a solution to control the body precisely and be independent towards unwanted misalignments; which results in improvements of the device performance and less variability of the performance over the dies of a wafer.

The term “matched” means here not only alignment in the sense that both dopant diffusion regions laterally extend such that their lateral surfaces are positioned on the same plane but also designs where the first diffusion layer has a pre-defined width relation to the second diffusion layer, i.e., the lateral surface of the first diffusion layer is in a pre-defined distance to the lateral surface of the second diffusion layer. In the embodiments shown below, designing this width relation is shown.

In an exemplary implementation of the semiconductor device, the first dopant implantation region is obtained by a first implantation of a dopant to the trench; wherein the second dopant implantation region is obtained by a second implantation of a dopant to the trench after formation of a spacer at the trench sidewalls; wherein the first dopant diffusion layer is obtained by diffusion or scattering of the first dopant implantation region in the lateral direction; and wherein the second dopant diffusion layer is obtained by diffusion or scattering of the second dopant implantation region in the lateral direction.

The matching of the extension of the second dopant diffusion region in the lateral direction with the extension of the first dopant diffusion layer in the lateral direction can be efficiently performed by using an appropriate spacer. By such implantation steps and diffusion/scattering steps together with the spacer, the width of the diffusion layers can be optimally controlled or designed.

Dopant diffusion can also happen in the vertical direction which is not discussed further since it is not further relevant to this disclosure. It is to be understood that this vertical diffusion is also covered by this disclosure.

In an exemplary implementation of the semiconductor device, the first dopant implantation region is formed by a first self-aligned implantation to the trench; and the second dopant implantation region is formed by a second self-aligned implantation to the trench which trench sidewalls are covered by the spacer.

These self-aligned processing steps provide precise control of the body design and are independent towards unwanted misalignments which results in improvement of the device performance and less variability of the performance over the dies of a wafer.

In an exemplary implementation of the semiconductor device, the semiconductor device comprises: a substrate of a first semiconductor doping type; a buffer layer of a first semiconductor doping type on top of the substrate; a drift layer of a first semiconductor doping type on top of the buffer layer; a current spreading layer of a first semiconductor doping type on top of the drift layer; a trench body region of a second semiconductor doping type formed in the trench on top of the current spreading layer; a trench source region of a first semiconductor doping type formed in the trench body region; a mesa Schottky region of a first semiconductor doping type formed in a mesa section of the semiconductor device; and a spacer gate region formed on the trench sidewalls; wherein the first dopant implantation region, the second dopant implantation region, the first dopant diffusion layer and the second dopant diffusion layer form the trench body region.

In such a semiconductor device the trench body region can be precisely formed by the above described design of the dopant diffusion layers.

This implementation corresponds to Embodiment 1 which is further described below with respect to FIG. 4a.

In an exemplary implementation of the semiconductor device, an edge of the trench body region is spaced from an edge of the trench sidewall.

In such a semiconductor device the space between the edge of the trench body region and the trench sidewall can be precisely designed.

This implementation corresponds to Embodiment 1 which is further described below with respect to FIG. 4a.

In an exemplary implementation of the semiconductor device, the semiconductor device comprises: a substrate of a first semiconductor doping type; a buffer layer of a first semiconductor doping type on top of the substrate; a drift layer of a first semiconductor doping type on top of the buffer layer; a current spreading layer of a first semiconductor doping type on top of the drift layer; a trench body region of a second semiconductor doping type formed in the trench on top of the current spreading layer; a trench source region of a first semiconductor doping type formed in the trench body region; a body-body separation region of a first semiconductor doping type formed in a mesa section of the semiconductor device; a mesa body region of a second semiconductor doping type formed on top of the body-body separation region; a mesa source region of a first semiconductor doping type formed on top of the mesa body region; and a spacer gate region formed on the trench sidewalls; wherein the first dopant implantation region, the second dopant implantation region, the first dopant diffusion layer and the second dopant diffusion layer form the trench body region.

In such a semiconductor device the trench body region can be precisely formed by the above-described design of the dopant diffusion layers.

This implementation corresponds to Embodiment 2 which is further described below with respect to FIG. 4b.

In an exemplary implementation of the semiconductor device, an edge of the trench body region is spaced from an edge of the trench sidewall.

Similar to the embodiment described above, also in this embodiment of the semiconductor device, the space between the edge of the trench body region and the trench sidewall can be precisely designed.

This implementation corresponds to Embodiment 2 which is further described below with respect to FIG. 4b.

In an exemplary implementation of the semiconductor device, the semiconductor device comprises: a substrate of a first semiconductor doping type; a buffer layer of a first semiconductor doping type on top of the substrate; a drift layer of a first semiconductor doping type on top of the buffer layer; a current spreading layer of a first semiconductor doping type on top of the drift layer; a trench body region of a second semiconductor doping type formed in the trench on top of the current spreading layer; a trench source region of a first semiconductor doping type formed in the trench body region; a body-body separation region of a first semiconductor doping type formed in a mesa section of the semiconductor device; a mesa body region of a second semiconductor doping type formed on top of the body-body separation region; a mesa source region of a first semiconductor doping type formed on top of the mesa body region; and a mesa body contact formed on top of the mesa body region for electrically connecting the mesa body region; and a spacer gate region formed on the trench sidewalls; wherein the trench body region is formed by the first dopant implantation region, the second dopant implantation region, the first dopant diffusion layer and the second dopant diffusion layer.

Also in this implementation of the semiconductor device having a mesa body contact, the trench body region can be precisely produced as described above.

This implementation corresponds to Embodiment 3 which is further described below without reference to the Figures.

In an exemplary implementation of the semiconductor device, an edge of the trench body region is spaced from an edge of the trench sidewall.

Also in this embodiment of the semiconductor device, the space between the edge of the trench body region and the trench sidewall can be precisely designed as described above.

This implementation corresponds to Embodiment 3 which is further described below without reference to the Figures.

In an exemplary implementation of the semiconductor device, an edge of the trench body region is aligned to an edge of the trench sidewall.

The alignment of the edge of the trench body region with the edge of the trench sidewall can be precisely produced such that both ones can lie on a common plane.

This implementation corresponds to Embodiments 4 and 5 which are further described below with respect to FIGS. 5a and 5b and to Embodiment 6 which is not represented by a figure.

In an exemplary implementation, the semiconductor device comprises a second trench body region formed below the trench body region; wherein an edge of the second trench body region is spaced from an edge of the trench sidewall.

This implementation corresponds to Embodiment 7 which is further described below with respect to FIG. 6a.

In an exemplary implementation of the semiconductor device, the second trench body region is formed by another first dopant implantation region, another second dopant implantation region, another first dopant diffusion layer and another second dopant diffusion layer.

This implementation corresponds to Embodiment 7 which is further described below with respect to FIG. 6a.

In an exemplary implementation, the semiconductor device comprises a second trench body region formed below the trench body region; wherein an edge of the second trench body region is spaced from an edge of the trench sidewall.

This implementation corresponds to Embodiment 8 which is further described below with respect to FIG. 6b.

In an exemplary implementation of the semiconductor device, the second trench body region is formed by another first dopant implantation region, another second dopant implantation region, another first dopant diffusion layer and another second dopant diffusion layer.

This implementation corresponds to Embodiment 8 which is further described below with respect to FIG. 6b.

In an exemplary implementation, the semiconductor device comprises a second trench body region formed below the trench body region; wherein an edge of the second trench body region is spaced from an edge of the trench sidewall.

This implementation corresponds to Embodiment 9 which is not shown in any Figure.

In an exemplary implementation of the semiconductor device, the second trench body region is formed by another first dopant implantation region, another second dopant implantation region, another first dopant diffusion layer and another second dopant diffusion layer.

This implementation corresponds to Embodiment 9 which is not shown in any Figure.

In an exemplary implementation, the semiconductor device comprises a second trench body region formed below the trench body region; wherein an edge of the second trench body region is spaced from an edge of the trench sidewall.

This implementation corresponds to Embodiment 10 which is further described below with respect to FIG. 7a.

In an exemplary implementation of the semiconductor device, the second trench body region is formed by another first dopant implantation region, another second dopant implantation region, another first dopant diffusion layer and another second dopant diffusion layer.

This implementation corresponds to Embodiment 10 which is further described below with respect to FIG. 7a.

In an exemplary implementation, the semiconductor device comprises a second trench body region formed below the trench body region; wherein an edge of the second trench body region is spaced from an edge of the trench sidewall.

This implementation corresponds to Embodiment 11 which is further described below with respect to FIG. 7b.

In an exemplary implementation of the semiconductor device, the second trench body region is formed by another first dopant implantation region, another second dopant implantation region, another first dopant diffusion layer and another second dopant diffusion layer.

This implementation corresponds to Embodiment 11 which is further described below with respect to FIG. 7b.

In an exemplary implementation, the semiconductor device comprises a second trench body region formed below the trench body region; wherein an edge of the second trench body region is spaced from an edge of the trench sidewall.

This implementation corresponds to Embodiment 12 which is not shown in any Figure.

In an exemplary implementation of the semiconductor device, the second trench body region is formed by another first dopant implantation region, another second dopant implantation region, another first dopant diffusion layer and another second dopant diffusion layer.

This implementation corresponds to Embodiment 12 which is not shown in any Figure.

According to a second aspect, the disclosure relates to a method for manufacturing a semiconductor device, the method comprising: forming a die layer; forming a trench in the die layer, the trench comprising a trench bottom and trench side walls; implanting a dopant to the trench to form a first dopant implantation region below the trench bottom; forming a spacer at the trench sidewalls; and implanting a dopant to the trench which trench sidewalls are covered by the spacer to form a second dopant implantation region below the first dopant implantation region; wherein a thickness of the spacer is matched to a width of a second dopant diffusion layer which is formed by a diffusion from the second dopant implantation region in a lateral direction.

Such method provides a solution to control the body design precisely and be independent towards unwanted misalignments; which results in improvements of the device performance and less variability of the performance over the dies of a wafer. The solution is based on a spacer design that allows precise control of the diffusion layer dimensions.

In an exemplary implementation of the method, the first dopant implantation region is formed by a first self-aligned implantation to the trench; and the second dopant implantation region is formed by a second self-aligned implantation to the trench which trench sidewalls are covered by the spacer.

These self-aligned processing steps provide precise control of the body design and are independent towards unwanted misalignments which results in improvement of the device performance and less variability of the performance over the dies of a wafer.

### BRIEF DESCRIPTION OF THE DRAWINGS

Further embodiments of the disclosure will be described with respect to the following figures, in which:

FIG. 1 shows a schematic diagram illustrating the Drain-Source on-resistance (Rdson) over the pitch of the mesa section for a SiC trench planar Schottky Barrier Diode semiconductor device;

FIG. 2 shows a schematic cross section of a semiconductor device 100 according to the disclosure;

FIG. 3 shows a schematic diagram illustrating an exemplary process flow of a method for manufacturing a semiconductor device according to the disclosure;

FIG. 4a shows a schematic cross section of a semiconductor device 100a according to a first embodiment;

FIG. 4b shows a schematic cross section of a semiconductor device 100b according to a second embodiment;

FIG. 5a shows a schematic cross section of a semiconductor device 100c according to a fourth embodiment;

FIG. 5b shows a schematic cross section of a semiconductor device 100d according to a fifth embodiment;

FIG. 6a shows a schematic cross section of a semiconductor device 100e according to a seventh embodiment;

FIG. 6b shows a schematic cross section of a semiconductor device 100f according to an eighth embodiment;

FIG. 7a shows a schematic cross section of a semiconductor device 100g according to a tenth embodiment; and

FIG. 7b shows a schematic cross section of a semiconductor device 100h according to an eleventh embodiment.

### DETAILED DESCRIPTION OF EMBODIMENTS

In the following detailed description, reference is made to the accompanying drawings, which form a part thereof, and in which is shown by way of illustration specific aspects in which the disclosure may be practiced. It is understood that other aspects may be utilized and structural or logical changes may be made without departing from the scope of the disclosure. The following detailed description, therefore, is not to be taken in a limiting sense, and the scope of the disclosure is defined by the appended claims.

It is understood that comments made in connection with a described method may also hold true for a corresponding device or system configured to perform the method and vice versa. For example, if a specific method step is described, a corresponding device may include a unit to perform the described method step, even if such unit is not explicitly described or illustrated in the figures. Further, it is understood that the features of the various exemplary aspects described herein may be combined with each other, unless specifically noted otherwise.

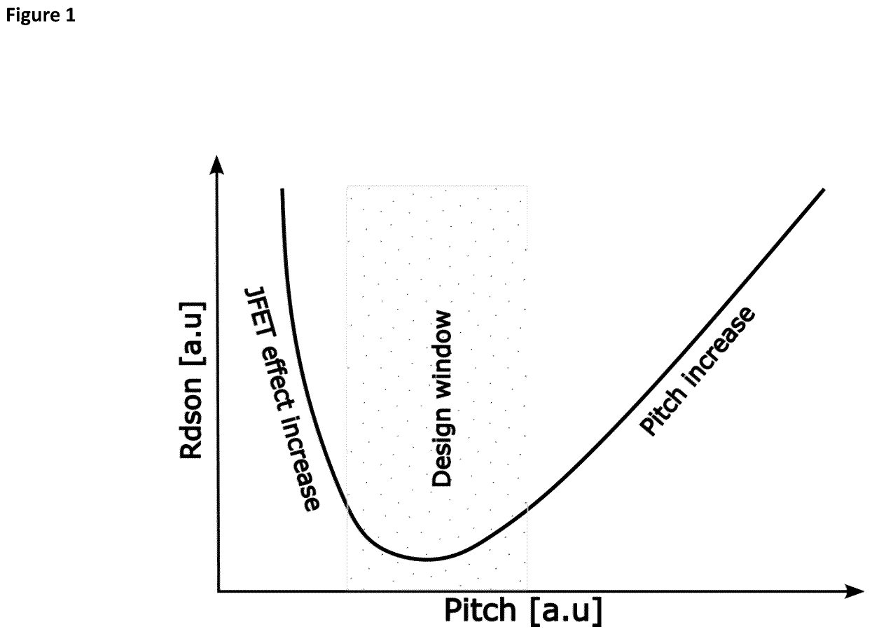

FIG. 1 shows a schematic diagram illustrating the Drain-Source on-resistance (Rdson) over the pitch of the mesa section for a SiC trench planar Schottky Barrier Diode semiconductor device.

SiC devices show a given process window for optimized Rdson performance as can be seen from FIG. 1. Pitch shrink is planned in next generation semiconductor devices in order to further reduce Rdson. This leads to strong counter-productive Rdson increase because of enhanced JFET action.

From FIG. 1 it can be seen that by reducing the pitch (e.g. in next generation semiconductor devices), Rdson is reduced until a minimum value of Rdson is reached. Further pitch reduction results in increase of Rdson which is cause by strong JFET action.

The disclosure presents a solution for designing a semiconductor device with a better control of the JFET action in order to allow extending the minimum value of Rdson to lower pitch values (in other words: to allow pitch reduction while keeping the JFET action under control).

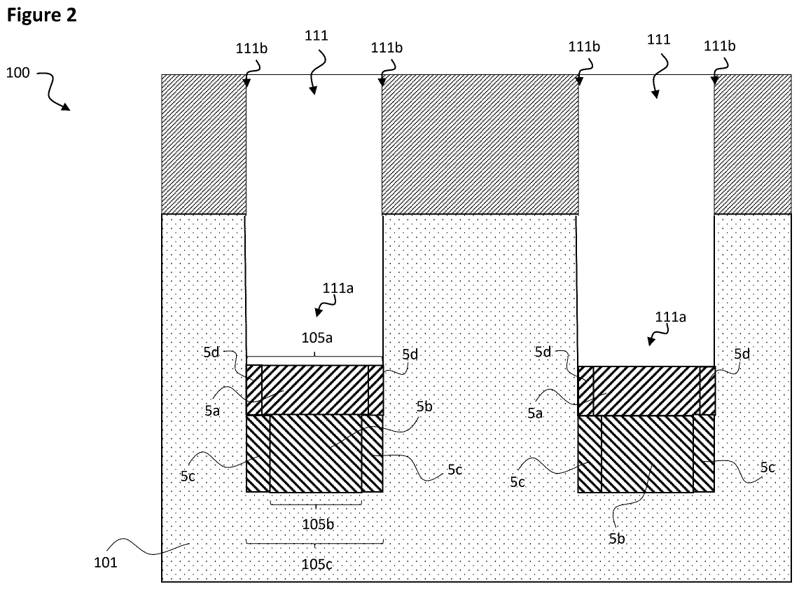

FIG. 2 shows a schematic cross section of a semiconductor device 100 according to the disclosure.

The semiconductor device 100 comprises: a die layer 101; and a trench 111 extending into the die layer 101. The trench 111 comprises a trench bottom 111a and trench side walls 111b. In FIG. 2, an exemplary number of two trenches 111 is shown as an example. Any other number of trenches 111 can be included in the die layer 101.

The semiconductor device 100 comprises: a first dopant implantation region 5a arranged below the trench bottom 111a; a second dopant implantation region 5b arranged below the first dopant implantation region 5a; a first dopant diffusion layer 5d extending laterally of the first dopant implantation region 5a; and a second dopant diffusion layer 5c extending laterally of the second dopant implantation region 5b.

An extension 105c of the second dopant diffusion region 5c in the lateral direction matches an extension of the first dopant diffusion layer 5d in the lateral direction.

Such device provides a solution to control the body design precisely and be independent towards unwanted misalignments; which results in improvements of the device performance and less variability of the performance over the dies of a wafer.

The term “matched” means here not only alignment in the sense that both dopant diffusion regions 5c, 5d laterally extend such that their lateral surfaces are positioned on the same plane but also designs where the first diffusion layer has a pre-defined width relation to the second diffusion layer, i.e. the lateral surface of the first diffusion layer is in a pre-defined distance to the lateral surface of the second diffusion layer.

In the embodiments shown below, designing this width relation is shown.

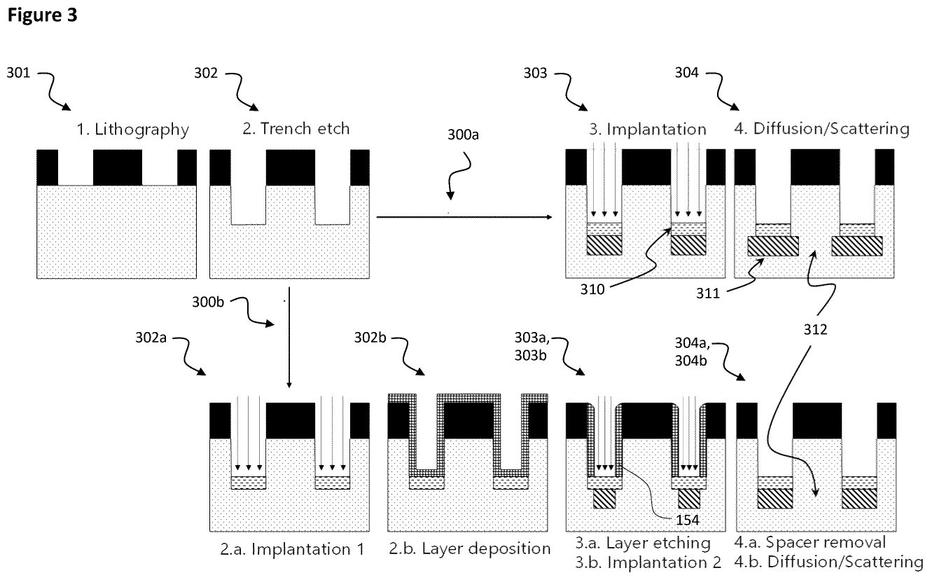

The first dopant implantation region 5a can be obtained by a first implantation of a dopant to the trench 111. The second dopant implantation region 5b can be obtained by a second implantation of a dopant to the trench 111 after formation of a spacer at the trench sidewalls 111b, e.g., a spacer 154 as shown below with respect to FIG. 3.

The first dopant diffusion layer 5d can be obtained by diffusion or scattering of the first dopant implantation region 5a in the lateral direction. The second dopant diffusion layer 5c can be obtained by diffusion or scattering of the second dopant implantation region 5b in the lateral direction.

Note that dopant diffusion can also happen in the vertical direction (not discussed further since it is not further relevant to this disclosure).

The first dopant implantation region 5a can be formed by a first self-aligned implantation to the trench 111 as described below. The second dopant implantation region 5b can be formed by a second self-aligned implantation to the trench 111 which trench sidewalls 111b are covered by the spacer 154 as described below.

FIG. 3 shows a schematic diagram illustrating an exemplary process flow of a method for manufacturing a semiconductor device according to the disclosure.

The solution presented in this disclosure relies on two main aspects: 1) The formation of the body by a self-aligned implantation through a spacer which is a less sensitive process to misalignments compared to lithography; and 2) The splitting of the implantation of the self-aligned body in more than one step, where the deeper portion of the body is implanted through a thicker (wider) spacer than the shallower part.

This approach is shown in a simplified form in FIG. 3 where a standard process 300a is compared to the solution for an improved process 300b presented in this disclosure.

The standard process 300a is shown in the top part of FIG. 3 including the steps 301, 302, 303, 304.

Step 1 (Lithography) 301: In this step 301, a photolithography mask is applied and developed to form openings on top of the semiconductor surface at regions where the future trenches will be formed.

Step 2 (Trench etch) 302: The trenches are formed.

Step 3 (Implantation) 303: The body is implanted with one or more different doses and energies. The use of several implants is often required to define the threshold voltage and form the bottom body/shield.

Step 4, 304: all the successive steps of the process flow are included here. The relevant matter to mention is the extension in space of the implanted body due to scattering (for example in case of SiC) or diffusion (for example in case of Si). For clarity, only the extension of 311 is shown. In reality, also 310 will extend, however, the deeper implants (higher energies) extend more.

The new concept or improved process 300b according to this disclosure is shown in the bottom part of FIG. 3 including the steps 301, 302, 302a, 302b, 303a, 303b, 304a, 304b.

Step 1 (Lithography) 301: In this step 301, a photolithography mask is applied and developed to form openings on top of the semiconductor surface at regions where the future trenches will be formed. This step 1 is similar to step 1 of the standard approach described above.

Step 2 (Trench etch) 302: The trenches are formed. This step 2 is similar to step 2 of the standard approach described above.

Step 2.a (Implantation 1) 302a: The shallow part 310 of the body is implanted self-aligned to the trench itself. Alternatively, a thin sacrificial dielectric can be deposited prior to the implantation to avoid sidewall unwanted implantation.

Step 2.b (Layer deposition) 302b: A layer is deposited in a conformal way. It can be of any material that can be blocking implanted species. Examples of such layer are dielectrics (such as oxide, nitride, etc.), metals, alloys, etc.

Step 3.a (Layer etching) 303a: By a combination of anisotropic and isotropic etching of the deposited layer, a spacer 154 is formed at the sidewalls of the trench.

Step 3.b. (Implantation 2) 303b: The deeper part 311 of the body is implanted self-aligned to the spacer 154. The spacer 154 acts as a mask. The deep body 311 formed is retracted towards the shallow body 310 proportionally to the width of the spacer 154 which in turns is proportional to the thickness of the deposited layer.

Step 4a, 304a: The spacer 154 is removed and the rest of the process takes place.

Step 4b, 304b: The relevant matter is the extension in space of the implanted body due to scattering (for example in case of SiC) or diffusion (for example in case of Si). However, the controlled retraction of the deep body 311 can be tuned in such a way to control the final edge of the deep body 311 towards the shallow body 310. The body to body space 312 can also be controlled.

Note that in the above-described simplified improved process flow 300b including the steps 301, 302, 302a, 302b, 303a, 303b, 304a, 304b, the shallow body 310 was implanted first. It has to be understood that any order is also covered.

Note also, that in the above-described simplified process, the shallow body 310 was implanted self-aligned to the trench. It has to be understood, that an implantation through a spacer is also possible in the same way as described for the deeper body 311. The thickness of this spacer can be adjusted to produce any desired effect on the final edge of the shallow body 310.

The advantage of the idea presented in this disclosure is to provide a solution to control the body design precisely and be independent towards unwanted misalignments; which results in improvements of the device performance and less variability of the performance over the dies of a wafer.

The process steps 301, 302, 302a, 302b, 303a, 303b, 304a, 304b of the improved process flow 300b described above can be formulated as a method according to the following.

A method for manufacturing a semiconductor device, e.g., a semiconductor device 100 shown in FIG. 2 or any of the semiconductor devices 100a, 100b, 100c, 100d, 100e, 100f, 100g, 100h described below comprises the following:
forming a die layer 101;
forming a trench 111 in the die layer 101, the trench 111 comprising a trench bottom 111a and trench side walls 111b, e.g., as shown in FIG. 2;
implanting a dopant to the trench 111 to form a first dopant implantation region 5a below the trench bottom 111a;
forming a spacer 154 at the trench sidewalls 111b, e.g., as shown in FIG. 3; and
implanting a dopant to the trench 111 which trench sidewalls 111b are covered by the spacer to form a second dopant implantation region 5b below the first dopant implantation region 5a;
wherein a thickness of the spacer is matched to a width of a second dopant diffusion layer 5c which is formed by a diffusion from the second dopant implantation region 5b in a lateral direction.

Such method may further comprise:
Forming the first dopant implantation region 5a by a first self-aligned implantation to the trench 111; and
forming the second dopant implantation region 5b by a second self-aligned implantation to the trench 111 which trench sidewalls 111b are covered by the spacer.

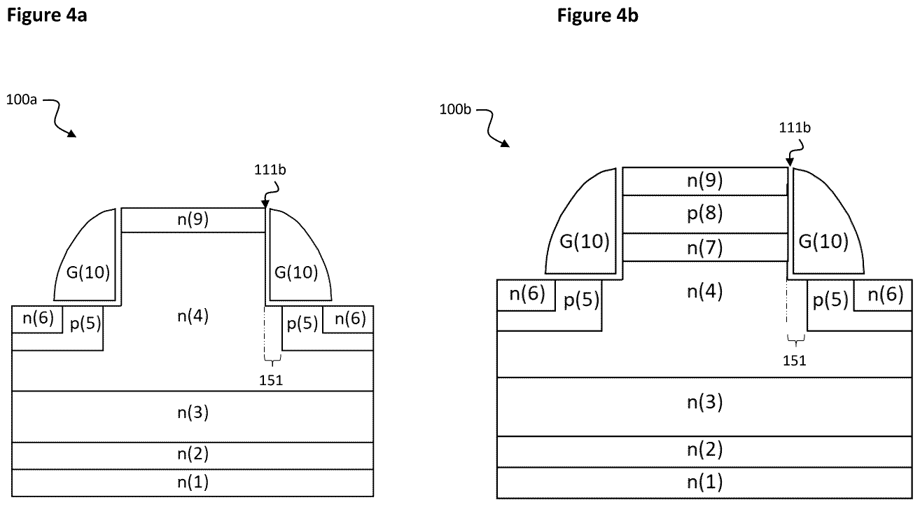

FIG. 4a shows a schematic cross section of a semiconductor device 100a according to a first embodiment. The semiconductor device 100a is an embodiment of the general design of a semiconductor device 100 presented and described above with respect to FIG. 2.

The semiconductor device 100a comprises: a substrate 1 of a first semiconductor doping type, denoted here with the reference sign n(1); a buffer layer 2 of a first semiconductor doping type, denoted here with the reference sign n(2), on top of the substrate 1; a drift layer 3 of a first semiconductor doping type, denoted here with the reference sign n(3), on top of the buffer layer 2; a current spreading layer 4 of a first semiconductor doping type, denoted here with the reference sign n(4), on top of the drift layer 3; a trench body region 5 of a second semiconductor doping type, denoted here with the reference sign p(5), formed in the trench 111 on top of the current spreading layer 4; a trench source region 6 of a first semiconductor doping type, denoted here with the reference sign n(6), formed in the trench body region 5; a mesa Schottky region 9 of a first semiconductor doping type, denoted here with the reference sign n(9), formed in a mesa section of the semiconductor device 100a; and a spacer gate region 10, denoted here with the reference sign G(10), formed on the trench sidewalls 111b.

The first dopant implantation region 5a, the second dopant implantation region 5b, the first dopant diffusion layer 5d and the second dopant diffusion layer 5c as described for the semiconductor device 100 shown in FIG. 2, form the trench body region 5.

An edge of the trench body region 5 is spaced 151 from an edge of the trench sidewall 111b. In this context, trench sidewall and edge of the trench sidewall mean the same.

The first embodiment of the semiconductor device 100a as shown in FIG. 4a can be a vertical device, for example. As described above, it may consist of a substrate of a first semiconductor doping type 1, a buffer layer of a first semiconductor doping type 2, a drift layer of a first semiconductor doping type 3 and a current spreading layer (CSL) of a first semiconductor doping type 4. Furthermore, the device 100a may be composed of a trench body region of a second semiconductor doping type 5, a trench source region of a first semiconductor doping type 6, a mesa Schottky region of a first semiconductor doping type 9 and a spacer gate region 10.

The trench body region 5 may be formed by implantation through a spacer 154 (as explained above with respect to FIG. 3). The edge of the trench body region 5 can be spaced 151 from the edge of the trench sidewall as shown in FIG. 4a.

The connection of the trench body (region 51, not shown in FIG. 4a) can be made in different ways. It can be realized in the third dimension, i.e., into the drawing plane of FIG. 4a, which is not shown in FIG. 4a, where region 51 can be implanted or regrown. It can be self-aligned to the trench edge or spaced with a distance that can be between 0 and the width of the trench region. It has to be understood that region 51 can be distributed in z-direction (multiple regions). There can exist more than only one region 51 in z-direction, i.e., the direction into the drawing plane. The shape of region 51 can also be arbitrarily. Any closed shape (circles, hexagons, triangles, rectangles, etc.) or any combination can be used. The connecting region 51 can be a stripe parallel to the trench source region 6. Region 51 can be, for example, as deep as (or deeper than) region 6 (to realize contact to region 5).

FIG. 4b shows a schematic cross section of a semiconductor device 100b according to a second embodiment. The semiconductor device 100b is an embodiment of the general design of a semiconductor device 100 presented and described above with respect to FIG. 2.

The semiconductor device 100b comprises: a substrate 1 of a first semiconductor doping type; a buffer layer 2 of a first semiconductor doping type on top of the substrate 1; a drift layer 3 of a first semiconductor doping type on top of the buffer layer 2; a current spreading layer 4 of a first semiconductor doping type on top of the drift layer 3; a trench body region 5 of a second semiconductor doping type formed in the trench 111 on top of the current spreading layer 4; a trench source region 6 of a first semiconductor doping type formed in the trench body region 5; a body-body separation region 7 of a first semiconductor doping type formed in a mesa section of the semiconductor device 100; a mesa body region 8 of a second semiconductor doping type formed on top of the body-body separation region 7; a mesa source region 9 of a first semiconductor doping type formed on top of the mesa body region 8; and a spacer gate region 10 formed on the trench sidewalls 111b.

The first dopant implantation region 5a, the second dopant implantation region 5b, the first dopant diffusion layer 5d and the second dopant diffusion layer 5c form the trench body region 5.

An edge of the trench body region 5 may be spaced 151 from an edge of the trench sidewall 111b as shown in FIG. 4b.

The second embodiment of the semiconductor device 100b as shown in FIG. 4b can be a vertical device. As described above, it may consist of a substrate of a first semiconductor doping type 1, a buffer layer of a first semiconductor doping type 2, a drift layer of a first semiconductor doping type 3 and a current spreading layer (CSL) of a first semiconductor doping type 4. Furthermore, the device 100b may be composed of a trench body region of a second semiconductor doping type 5, a trench source region of a first semiconductor doping type 6, a body-body separation region of a first semiconductor doping type 7, a mesa body region of a second semiconductor doping type 8, a mesa source region of a first semiconductor doping type 9 and a spacer gate region 10 as shown in FIG. 4b.

The connection between the mesa body region 8 to the trench body region 5 can be performed in the third dimension, i.e., into the drawing plane of FIG. 4b, through the region 51 (not shown in FIG. 4b). The connection of the mesa body region 8 and the connection of the trench body region 5 can also be realized separately and made in the third dimension, i.e., into the drawing plane of FIG. 4b. Body region 8 may be connected through region 52 (not shown in FIG. 4b) and trench body region 5 may be connected through region 51 (not shown in FIG. 4b). Here, region 51 can be implemented in the trench section while region 52 can be implemented in the mesa section of the semiconductor device. Other configurations for region 51 can be applied as well.

The trench body region 5 can be formed by implantation through a spacer 154 as shown in FIG. 3. The edge of the trench body region 5 may be spaced from the edge of the trench sidewall. In all cases, regions 51 and regions 52 can be electrically contacted by metallization (not shown here for clarity).

In the following, a third embodiment of the semiconductor device 100 shown in FIG. 2 is described. This third embodiment is not presented in the Figures. Reference signs of this third embodiment are corresponding to the reference signs of the other embodiments.

In this third embodiment, the semiconductor device comprises: a substrate 1 of a first semiconductor doping type; a buffer layer 2 of a first semiconductor doping type on top of the substrate 1; a drift layer 3 of a first semiconductor doping type on top of the buffer layer 2; a current spreading layer 4 of a first semiconductor doping type on top of the drift layer 3; a trench body region 5 of a second semiconductor doping type formed in the trench 111 on top of the current spreading layer 4; a trench source region 6 of a first semiconductor doping type formed in the trench body region 5; a body-body separation region 7 of a first semiconductor doping type formed in a mesa section of the semiconductor device; a mesa body region 8 of a second semiconductor doping type formed on top of the body-body separation region 7; a mesa source region 9 of a first semiconductor doping type formed on top of the mesa body region 8; a mesa body contact formed on top of the mesa body region 8 for electrically connecting the mesa body region 8; and a spacer gate region 10 formed on the trench sidewalls 111b.

The trench body region 5 is formed by the first dopant implantation region 5a, the second dopant implantation region 5b, the first dopant diffusion layer 5d and the second dopant diffusion layer 5c as shown in FIG. 2.

An edge of the trench body region 5 is spaced from an edge of the trench sidewall 111b.

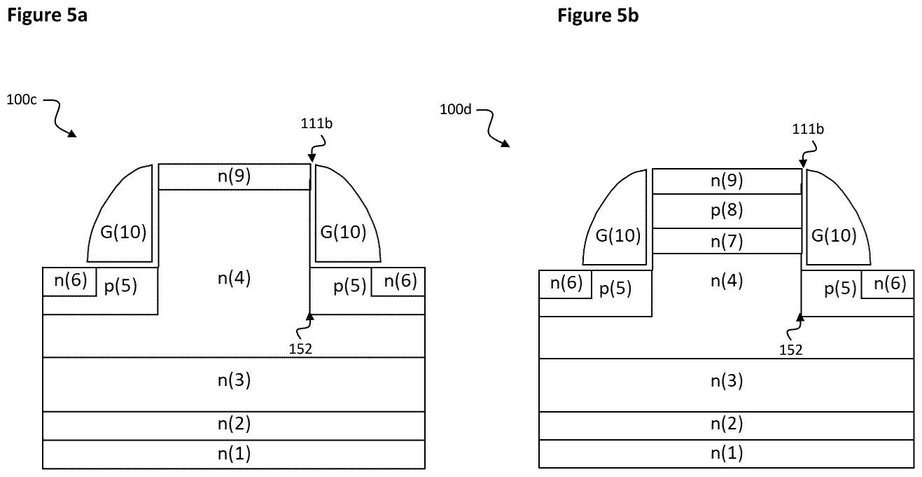

FIG. 5a shows a schematic cross section of a semiconductor device 100c according to a fourth embodiment. The semiconductor device 100c is an embodiment of the general design of a semiconductor device 100 presented and described above with respect to FIG. 2. The difference to the embodiment shown in FIG. 4a (and also FIG. 4b) is that in the embodiment of FIG. 4a (and also FIG. 4b), the trench body region 5 is not aligned with the trench sidewall 111b, i.e., there is a space 151 between the edge of the trench body region 5 and the trench sidewall 111b. In contrast, in the embodiment shown in FIG. 5a (and also FIG. 5b), the trench body region 5 is aligned with the trench sidewall 111b, i.e., there is no space between the edge of the trench body region 5 and the trench sidewall 111b, i.e., the trench body region 5 laterally extends up to the trench sidewall 111b.

The semiconductor device 100c comprises: a substrate 1 of a first semiconductor doping type; a buffer layer 2 of a first semiconductor doping type on top of the substrate 1; a drift layer 3 of a first semiconductor doping type on top of the buffer layer 2; a current spreading layer 4 of a first semiconductor doping type on top of the drift layer 3; a trench body region 5 of a second semiconductor doping type formed in the trench 111 on top of the current spreading layer 4; a trench source region 6 of a first semiconductor doping type formed in the trench body region 5; a mesa source region 9 of a first semiconductor doping type formed on top of the current spreading layer 4 in the mesa section; and a spacer gate region 10 formed on the trench sidewalls 111b.

An edge 152 of the trench body region 5 is aligned to an edge of the trench sidewall 111b as can be seen from FIG. 5a.

The fourth embodiment is similar to the first one. However the trench body region 5 is implanted through a spacer with a thickness such as the edge of region 5 is aligned to the trench sidewall after scattering or diffusion.

FIG. 5b shows a schematic cross section of a semiconductor device 100d according to a fifth embodiment. The semiconductor device 100d is an embodiment of the general design of a semiconductor device 100 presented and described above with respect to FIG. 2.

The semiconductor device 100d comprises: a substrate 1 of a first semiconductor doping type; a buffer layer 2 of a first semiconductor doping type on top of the substrate 1; a drift layer 3 of a first semiconductor doping type on top of the buffer layer 2; a current spreading layer 4 of a first semiconductor doping type on top of the drift layer 3; a trench body region 5 of a second semiconductor doping type formed in the trench 111 on top of the current spreading layer 4; a trench source region 6 of a first semiconductor doping type formed in the trench body region 5; a body-body separation region 7 of a first semiconductor doping type formed in a mesa section of the semiconductor device 100; a mesa body region 8 of a second semiconductor doping type formed on top of the body-body separation region 7; a mesa source region 9 of a first semiconductor doping type formed on top of the mesa body region 8; and a spacer gate region 10 formed on the trench sidewalls 111b.

An edge 152 of the trench body region 5 can be aligned to an edge of the trench sidewall 111b.

The fifth embodiment is similar to the second one. However, the trench body region 5 is implanted through a spacer with a thickness such as the edge of region 5 is aligned to the trench sidewall after scattering or diffusion).

In a sixth embodiment of the semiconductor device (not shown in the Figures), the semiconductor device comprises: a substrate 1 of a first semiconductor doping type; a buffer layer 2 of a first semiconductor doping type on top of the substrate 1; a drift layer 3 of a first semiconductor doping type on top of the buffer layer 2; a current spreading layer 4 of a first semiconductor doping type on top of the drift layer 3; a trench body region 5 of a second semiconductor doping type formed in the trench 111 on top of the current spreading layer 4; a trench source region 6 of a first semiconductor doping type formed in the trench body region 5; a body-body separation region 7 of a first semiconductor doping type formed in a mesa section of the semiconductor device; a mesa body region 8 of a second semiconductor doping type formed on top of the body-body separation region 7; a mesa source region 9 of a first semiconductor doping type formed on top of the mesa body region 8; a mesa body contact formed on top of the mesa body region 8 for electrically connecting the mesa body region 8; and a spacer gate region 10 formed on the trench sidewalls 111b.

an edge 152 of the trench body region 5 can be aligned to an edge of the trench sidewall 111b.

The sixth embodiment is similar to the third one. However the trench body region 5 is implanted through a spacer with a thickness such as the edge of region 5 is aligned to the trench sidewall after scattering or diffusion).

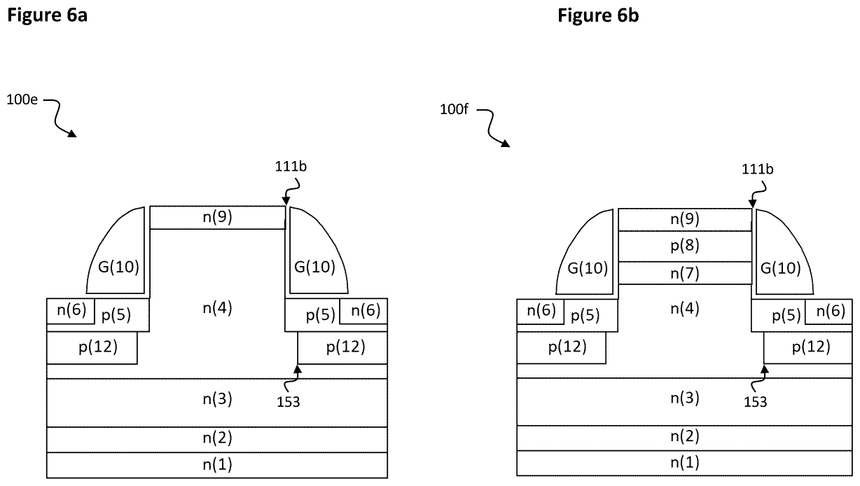

FIG. 6a shows a schematic cross section of a semiconductor device 100e according to a seventh embodiment. The semiconductor device 100e is an embodiment of the general design of a semiconductor device 100 presented and described above with respect to FIG. 2.

The semiconductor device 100e comprises: a substrate 1 of a first semiconductor doping type; a buffer layer 2 of a first semiconductor doping type on top of the substrate 1; a drift layer 3 of a first semiconductor doping type on top of the buffer layer 2; a current spreading layer 4 of a first semiconductor doping type on top of the drift layer 3; a trench body region 5 of a second semiconductor doping type formed in the trench 111 above the current spreading layer 4; a trench source region 6 of a first semiconductor doping type formed in the trench body region 5; a mesa source region 9 of a first semiconductor doping type formed on top of the current spreading layer 4 in the mesa section; and a spacer gate region 10 formed on the trench sidewalls 111b.

The semiconductor device 100e comprises: a second trench body region 12 formed below the trench body region 5. An edge 153 of the second trench body region 12 may be spaced from an edge of the trench sidewall 111b as shown in FIG. 6a.

The second trench body region 12 may be formed by another first dopant implantation region 5a, another second dopant implantation region 5b, another first dopant diffusion layer 5d and another second dopant diffusion layer 5c according to FIG. 2. Alternatively, the first dopant implantation region 5a and the first dopant diffusion layer 5d can be skipped.

The seventh embodiment is similar to the fourth one. Additionally, it includes another body region 12 (denoted in this disclosure as second trench body region 12) which is deeper than body region 5 (denoted in this disclosure as trench body region 5 or first trench body region 5). Body region 12 (denoted in this disclosure as second trench body region 12) is formed similar to Body region 5 (implantation through a spacer). The spacer of body region 12 is thicker (wider) than the one of body region 5. The case where it is narrower is also possible.

Body region 5 can be created by implant through a spacer as described above with respect to FIG. 3, but body region 5 can also be the combination of the shallow implant 310 and the deep implant 311 as also described in FIG. 3. In a preferred implementation, only deep implant 311 is done through a spacer 154 as shown in FIG. 3.

FIG. 6b shows a schematic cross section of a semiconductor device 100f according to an eighth embodiment. The semiconductor device 100f is an embodiment of the general design of a semiconductor device 100 presented and described above with respect to FIG. 2.

The semiconductor device 100f comprises: a substrate 1 of a first semiconductor doping type; a buffer layer 2 of a first semiconductor doping type on top of the substrate 1; a drift layer 3 of a first semiconductor doping type on top of the buffer layer 2; a current spreading layer 4 of a first semiconductor doping type on top of the drift layer 3; a trench body region 5 of a second semiconductor doping type formed in the trench 111 above the current spreading layer 4; a trench source region 6 of a first semiconductor doping type formed in the trench body region 5; a body-body separation region 7 of a first semiconductor doping type formed in a mesa section of the semiconductor device 100; a mesa body region 8 of a second semiconductor doping type formed on top of the body-body separation region 7; a mesa source region 9 of a first semiconductor doping type formed on top of the mesa body region 8; and a spacer gate region 10 formed on the trench sidewalls 111b.

The semiconductor device 100f comprises: a second trench body region 12 formed below the trench body region 5. An edge 153 of the second trench body region 12 may be spaced from an edge of the trench sidewall 111b as shown in FIG. 6b.

The second trench body region 12 may be formed by another first dopant implantation region 5a, another second dopant implantation region 5b, another first dopant diffusion layer 5d and another second dopant diffusion layer 5c as shown in FIG. 2. Alternatively, the first dopant implantation region 5a and the first dopant diffusion layer 5d can be skipped.

The eighth embodiment is similar to the fifth one. Additionally, it includes another body region 12 which is deeper than body region 5. Body region 12 is formed similar to body region 5 (implantation through a spacer). The spacer of body region 12 is thicker (wider) than the one of body region 5. The case where it is narrower is also possible.

In a ninth embodiment (not shown in the Figures), the semiconductor device comprises: a substrate 1 of a first semiconductor doping type; a buffer layer 2 of a first semiconductor doping type on top of the substrate 1; a drift layer 3 of a first semiconductor doping type on top of the buffer layer 2; a current spreading layer 4 of a first semiconductor doping type on top of the drift layer 3; a trench body region 5 of a second semiconductor doping type formed in the trench 111 above the current spreading layer 4; a trench source region 6 of a first semiconductor doping type formed in the trench body region 5; a body-body separation region 7 of a first semiconductor doping type formed in a mesa section of the semiconductor device 100; a mesa body region 8 of a second semiconductor doping type formed on top of the body-body separation region 7; a mesa source region 9 of a first semiconductor doping type formed on top of the mesa body region 8; and a spacer gate region 10 formed on the trench sidewalls 111b.

The semiconductor device comprises a second trench body region 12 formed below the trench body region 5. An edge 153 of the second trench body region 12 may be spaced from an edge of the trench sidewall 111b.

The second trench body region 12 may be formed by another first dopant implantation region 5a, another second dopant implantation region 5b, another first dopant diffusion layer 5d and another second dopant diffusion layer 5c as shown in FIG. 2. Alternatively, the first dopant implantation region 5a and the first dopant diffusion layer 5d can be skipped.

The ninth embodiment is similar to the sixth one. Additionally, it includes another body region 12 which is deeper than body region 5. Body region 12 is formed similar to body region 5 (implantation through a spacer). The spacer of body region 12 is thicker (wider) than the one of body region 5. The case where it is narrower is also possible.

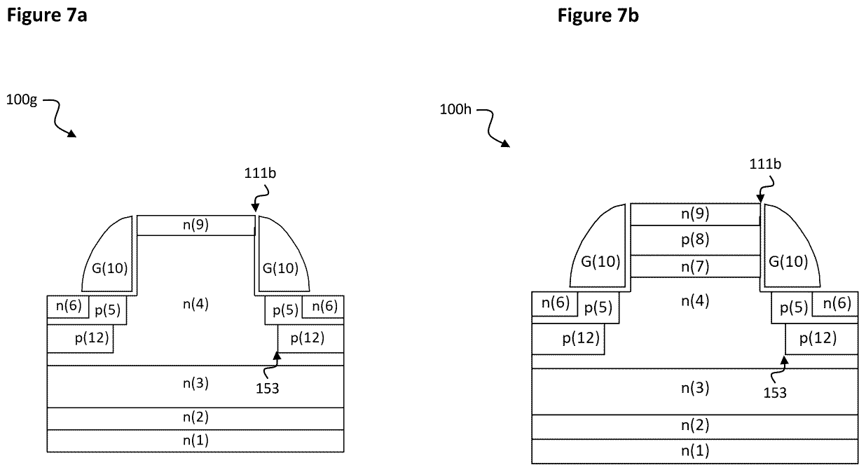

FIG. 7a shows a schematic cross section of a semiconductor device 100g according to a tenth embodiment. The semiconductor device 100g is an embodiment of the general design of a semiconductor device 100 presented and described above with respect to FIG. 2. The difference to the embodiment shown in FIG. 6a is that in the embodiment of FIG. 7a, the trench body region 5 is not aligned with the trench sidewall 111b, i.e., there is a space between the edge of the trench body region 5 and the trench sidewall 111b. In contrast, in the embodiment shown in FIG. 6a, the trench body region 5 is aligned with the trench sidewall 111b, i.e., there is no space between the edge of the trench body region 5 and the trench sidewall 111b, i.e., the trench body region 5 laterally extends up to the trench sidewall 111b.

The semiconductor device 100g comprises: a substrate 1 of a first semiconductor doping type, denoted here with the reference sign n(1); a buffer layer 2 of a first semiconductor doping type, denoted here with the reference sign n(2), on top of the substrate 1; a drift layer 3 of a first semiconductor doping type, denoted here with the reference sign n(3), on top of the buffer layer 2; a current spreading layer 4 of a first semiconductor doping type, denoted here with the reference sign n(4), on top of the drift layer 3; a trench body region 5 of a second semiconductor doping type, denoted here with the reference sign p(5), formed in the trench 111 above the current spreading layer 4; a trench source region 6 of a first semiconductor doping type, denoted here with the reference sign n(6), formed in the trench body region 5; a mesa Schottky region 9 of a first semiconductor doping type, denoted here with the reference sign n(9), formed in a mesa section of the semiconductor device 100a; and a spacer gate region 10, denoted here with the reference sign G(10), formed on the trench sidewalls 111b.

The semiconductor device 100g comprises a second trench body region 12 formed below the trench body region 5.

An edge 153 of the second trench body region 12 may be spaced from an edge of the trench sidewall 111b as shown in FIG. 7a.

The second trench body region 12 may be formed by another first dopant implantation region 5a, another second dopant implantation region 5b, another first dopant diffusion layer 5d and another second dopant diffusion layer 5c as shown in FIG. 2.

The tenth embodiment is similar to the first one. Additionally, it includes another body region 12 which is deeper than body region 5. Body region 12 is formed similar to body region 5 (implantation through a spacer). The spacer of body region 12 is thicker (wider) than the one of body region 5. The case where it is narrower is also possible.

FIG. 7b shows a schematic cross section of a semiconductor device 100h according to an eleventh embodiment. The semiconductor device 100h is an embodiment of the general design of a semiconductor device 100 presented and described above with respect to FIG. 2. The difference to the embodiment shown in FIG. 6b is that in the embodiment of FIG. 7b, the trench body region 5 is not aligned with the trench sidewall 111b, i.e., there is a space between the edge of the trench body region 5 and the trench sidewall 111b. In contrast, in the embodiment shown in FIG. 6b, the trench body region 5 is aligned with the trench sidewall 111b, i.e., there is no space between the edge of the trench body region 5 and the trench sidewall 111b, i.e., the trench body region 5 laterally extends up to the trench sidewall 111b.

The semiconductor device 100h comprises: a substrate 1 of a first semiconductor doping type; a buffer layer 2 of a first semiconductor doping type on top of the substrate 1; a drift layer 3 of a first semiconductor doping type on top of the buffer layer 2; a current spreading layer 4 of a first semiconductor doping type on top of the drift layer 3; a trench body region 5 of a second semiconductor doping type formed in the trench 111 above the current spreading layer 4; a trench source region 6 of a first semiconductor doping type formed in the trench body region 5; a body-body separation region 7 of a first semiconductor doping type formed in a mesa section of the semiconductor device 100; a mesa body region 8 of a second semiconductor doping type formed on top of the body-body separation region 7; a mesa source region 9 of a first semiconductor doping type formed on top of the mesa body region 8; and a spacer gate region 10 formed on the trench sidewalls 111b.

The semiconductor device 100h comprises a second trench body region 12 formed below the trench body region 5.

An edge 153 of the second trench body region 12 is spaced from an edge of the trench sidewall 111b.

The second trench body region 12 may be formed by another first dopant implantation region 5a, another second dopant implantation region 5b, another first dopant diffusion layer 5d and another second dopant diffusion layer 5c as shown in FIG. 2.

The eleventh embodiment is similar to the second one. Additionally, it includes another body region 12 which is deeper than body region 5. Body region 12 is formed similar to body region 5 (implantation through a spacer). The spacer of body region 12 is thicker (wider) than the one of body region 5. The case where it is narrower is also possible.

In a twelfth embodiment (not shown in the Figures) the semiconductor device comprises: a substrate 1 of a first semiconductor doping type; a buffer layer 2 of a first semiconductor doping type on top of the substrate 1; a drift layer 3 of a first semiconductor doping type on top of the buffer layer 2; a current spreading layer 4 of a first semiconductor doping type on top of the drift layer 3; a trench body region 5 of a second semiconductor doping type formed in the trench 111 above the current spreading layer 4; a trench source region 6 of a first semiconductor doping type formed in the trench body region 5; a body-body separation region 7 of a first semiconductor doping type formed in a mesa section of the semiconductor device 100; a mesa body region 8 of a second semiconductor doping type formed on top of the body-body separation region 7; a mesa source region 9 of a first semiconductor doping type formed on top of the mesa body region 8; and a spacer gate region 10 formed on the trench sidewalls 111b. Additionally, the semiconductor device may comprise a mesa body contact (not shown in the Figures). This mesa body contact may be drawn as deep as region 9, however, it can also be deeper than region 9.

The mesa body contact is included in the mesa region and makes electrical connection to the mesa body region 8. The mesa body contact can also be implemented in the mesa region as disconnected islands (not shown here for simplicity). The mesa body contact can be implemented in the center of the mesa region (preferred case), but it can also be misaligned to one side. It can even be completely consuming locally the trench source region 6 on one side and/or the other.

A trench body contact (not shown here) can be formed in the third dimension (below the drawing plane shown in the Figures) or via metallization (not shown here for clarity). A stripe configuration can also be implemented.

The trench body region 5 can be formed by implantation through a spacer, e.g., as described above with respect to FIG. 3. In this twelfth embodiment, the edge of the trench body region 5 is spaced from the edge of the trench sidewall 111b.

The semiconductor device comprises a second trench body region 12 formed below the trench body region 5.

An edge 153 of the second trench body region 12 is spaced from an edge of the trench sidewall 111b.

The second trench body region 12 may be formed by another first dopant implantation region 5a, another second dopant implantation region 5b, another first dopant diffusion layer 5d and another second dopant diffusion layer 5c as shown in FIG. 2.

The twelfth embodiment is similar to the third one. Additionally, it includes another body region 12 which is deeper than body region 5. Body region 12 is formed similar to body region 5 (implantation through a spacer). The spacer of body region 12 is thicker (wider) than the one of body region 5. The case where it is narrower is also possible.

In a thirteenth embodiment (not shown in the Figures) the semiconductor device can be a vertical device for which the doping type of the substrate 1 is of opposite doping type to the doping type of the drift layer 3. The device forms an IGBT structure.

In a fourteenth embodiment (not shown in the Figures) the semiconductor device can be a complementary vertical device for which all semiconductor regions of embodiments 1-13 are of a reversed doping type.

In a fifteenth embodiment (not shown in the Figures) the semiconductor device the implantation of the body can be performed through any number of spacers (not limited to 2). Each implantation through one spacer can be a sequence of many sub-implants with different energies and/or doses.

In a sixteenth embodiment (not shown in the Figures), all previous embodiments can be related to Silicon, SiC, GaN or Ga2O3.

In a seventeenth embodiment (not shown in the Figures), all previous embodiments can be related to other than vertical devices (lateral devices, semi-vertical devices).

In an eighteenth embodiment (not shown in the Figures), all previous embodiments can be related to devices that have no mesa region (example: planar gate MOSFETs). In this case the process is started by forming a step with a given height with any material (standard hard masks, oxide, nitride, metal, alloys, etc.). This step will serve as a seed to form the spacer (similar to the mesa region in previous embodiments).

In a nineteenth embodiment (not shown in the Figures), all previous embodiments can be related to devices where the CSL region 4 is less deep than the body region 12 or the body region 5 or the source region 6.

The disclosure provides a solution to align and control the body region to control the body to body spacing, even for deep bodies. This allows minimizing the JFET effect which improves Rdson to allow shrinking the pitch for advanced technologies (widening of the initial design window). The disclosure presents usage of a spacer. This allows to eliminate the unwanted lithography misalignments and improve the wafer uniformity. The disclosure presents a mechanism to combine several spacers with increased thickness. This allows to form a straight body edge (box profile) or opened triangular JEFT region.

The technical solution described in this disclosure can be applied to other semiconductor trench devices, for example to MOSFET and IGBT, fabricated using silicon, gallium oxide or other semiconductor material technologies.

While a particular feature or aspect of the disclosure may have been disclosed with respect to only one of several implementations, such feature or aspect may be combined with one or more other features or aspects of the other implementations as may be desired and advantageous for any given or particular application. Furthermore, to the extent that the terms “include”, “have”, “with”, or other variants thereof are used in either the detailed description or the claims, such terms are intended to be inclusive in a manner similar to the term “comprise”. Also, the terms “exemplary”, “for example” and “e.g.” are merely meant as an example, rather than the best or optimal. The terms “coupled” and “connected”, along with derivatives may have been used. It should be understood that these terms may have been used to indicate that two elements cooperate or interact with each other regardless whether they are in direct physical or electrical contact, or they are not in direct contact with each other.

Although specific aspects have been illustrated and described herein, it will be appreciated by those of ordinary skill in the art that a variety of alternate and/or equivalent implementations may be substituted for the specific aspects shown and described without departing from the scope of the disclosure. This application is intended to cover any adaptations or variations of the specific aspects discussed herein.

Although the elements in the following claims are recited in a particular sequence with corresponding labeling, unless the claim recitations otherwise imply a particular sequence for implementing some or all of those elements, those elements are not necessarily intended to be limited to being implemented in that particular sequence.

Many alternatives, modifications, and variations will be apparent to those skilled in the art in light of the above teachings. Of course, those skilled in the art readily recognize that there are numerous applications of the disclosure beyond those described herein. While the disclosure has been described with reference to one or more particular embodiments, those skilled in the art recognize that many changes may be made thereto without departing from the scope of the disclosure. It is therefore to be understood that within the scope of the appended claims and their equivalents, the disclosure may be practiced otherwise than as specifically described herein.

What is claimed is:

1. A semiconductor device, comprising:
a die layer;
a trench extending into the die layer, wherein the trench comprises a trench bottom and trench side walls;
a first dopant implantation region arranged below the trench bottom;
a second dopant implantation region arranged below the first dopant implantation region;
a first dopant diffusion layer extending laterally of the first dopant implantation region; and
a second dopant diffusion layer extending laterally of the second dopant implantation region;
wherein an extension of the second dopant diffusion region in the lateral direction matches an extension of the first dopant diffusion layer in the lateral direction.

2. The semiconductor device of claim 1,
wherein the first dopant implantation region is obtained by a first implantation of a dopant to the trench;
wherein the second dopant implantation region is obtained by a second implantation of a dopant to the trench after formation of a spacer at the trench sidewalls;
wherein the first dopant diffusion layer is obtained by diffusion or scattering of the first dopant implantation region in the lateral direction; and
wherein the second dopant diffusion layer is obtained by diffusion or scattering of the second dopant implantation region in the lateral direction.

3. The semiconductor device of claim 1,
wherein the first dopant implantation region is formed by a first self-aligned implantation to the trench; and
wherein the second dopant implantation region is formed by a second self-aligned implantation to the trench which trench sidewalls are covered by the spacer.

4. The semiconductor device of claim 1, comprising:
a substrate of a first semiconductor doping type;
a buffer layer of a first semiconductor doping type on top of the substrate;
a drift layer of a first semiconductor doping type on top of the buffer layer;
a current spreading layer of a first semiconductor doping type on top of the drift layer;
a trench body region of a second semiconductor doping type formed in the trench on top of the current spreading layer;
a trench source region of a first semiconductor doping type formed in the trench body region;
a mesa Schottky region of a first semiconductor doping type formed in a mesa section of the semiconductor device; and
a spacer gate region formed on the trench sidewalls;
wherein the first dopant implantation region, the second dopant implantation region, the first dopant diffusion layer and the second dopant diffusion layer (5c) form the trench body region.

5. The semiconductor device of claim 4,
wherein an edge of the trench body region is spaced from an edge of the trench sidewall.

6. The semiconductor device of claim 1, comprising:
a substrate of a first semiconductor doping type;
a buffer layer of a first semiconductor doping type on top of the substrate;
a drift layer of a first semiconductor doping type on top of the buffer layer;
a current spreading layer of a first semiconductor doping type on top of the drift layer;
a trench body region of a second semiconductor doping type formed in the trench on top of the current spreading layer;
a trench source region of a first semiconductor doping type formed in the trench body region;
a body-body separation region of a first semiconductor doping type formed in a mesa section of the semiconductor device;
a mesa body region of a second semiconductor doping type formed on top of the body-body separation region;
a mesa source region of a first semiconductor doping type formed on top of the mesa body region; and
a spacer gate region formed on the trench sidewalls;
wherein the first dopant implantation region, the second dopant implantation region, the first dopant diffusion layer and the second dopant diffusion layer form the trench body region.

7. The semiconductor device of claim 6,
wherein an edge of the trench body region is spaced from an edge of the trench sidewall.

8. The semiconductor device of claim 1, comprising:
a substrate of a first semiconductor doping type;
a buffer layer of a first semiconductor doping type on top of the substrate;
a drift layer of a first semiconductor doping type on top of the buffer layer;
a current spreading layer of a first semiconductor doping type on top of the drift layer;
a trench body region of a second semiconductor doping type formed in the trench on top of the current spreading layer;
a trench source region of a first semiconductor doping type formed in the trench body region;
a body-body separation region of a first semiconductor doping type formed in a mesa section of the semiconductor device;
a mesa body region of a second semiconductor doping type formed on top of the body-body separation region;
a mesa source region of a first semiconductor doping type formed on top of the mesa body region; and
a mesa body contact formed on top of the mesa body region for electrically connecting the mesa body region; and
a spacer gate region formed on the trench sidewalls;
wherein the trench body region is formed by the first dopant implantation region, the second dopant implantation region, the first dopant diffusion layer and the second dopant diffusion layer.

9. The semiconductor device of claim 8,
wherein an edge of the trench body region is spaced from an edge of the trench sidewall.

10. The semiconductor device of claim 4,
wherein an edge of the trench body region is aligned to an edge of the trench sidewall).

11. The semiconductor device of claim 6,
wherein an edge of the trench body region is aligned to an edge of the trench sidewall.

12. The semiconductor device of claim 8,
wherein an edge of the trench body region is aligned to an edge of the trench sidewall.

13. A method for manufacturing a semiconductor device, the method comprising:
forming a die layer;
forming a trench in the die layer, wherein the trench comprises a trench bottom and trench side walls;
implanting a dopant to the trench to form a first dopant implantation region below the trench bottom;
forming a spacer at the trench sidewalls; and
implanting a dopant to the trench which trench sidewalls are covered by the spacer to form a second dopant implantation region below the first dopant implantation region;
wherein a thickness of the spacer is matched to a width of a second dopant diffusion layer which is formed by a diffusion from the second dopant implantation region in a lateral direction.

14. The method of claim 13,
wherein the first dopant implantation region is formed by a first self-aligned implantation to the trench; and
wherein the second dopant implantation region is formed by a second self-aligned implantation to the trench which trench sidewalls are covered by the spacer.
